(19) United States
(12) Patent Application Publication
(10) Pub. No.: US 2016/0204003 A1
(43) Pub. Date: Jul. 14, 2016

(54) METHOD OF FORMING ASPER-SILVER ON A LEAD FRAME

(71) Applicants: Yiu Fai KWAN, Tsuen Wai (HK); Yu Lung LAM, Kwai Chung (HK); Chun Ho YAU, Kwai Chung (HK); Wing Lam AU, Kwai Chung (HK)

(72) Inventors: Yiu Fai KWAN, Tsuen Wai (HK); Yu Lung LAM, Kwai Chung (HK); Chun Ho YAU, Kwai Chung (HK); Wing Lam AU, Kwai Chung (HK)

(21) Appl. No.: 14/592,548

(22) Filed: Jan. 8, 2015

(51) Int. Cl. H01L 21/48; C25D 3/46; C25D 5/02; C23C 18/31; C25D 5/18; C25D 7/12; C23C 28/02; H01L 21/288; C25D 5/10

(52) U.S. Cl. CPC H01L 21/4821; H01L 21/2885; C25D 3/46; C25D 5/022; C25D 5/10; C25D 5/18; C25D 7/12; C23C 28/023; C23C 18/31

(57) ABSTRACT

A method for plating a lead frame comprises the steps of plating the lead frame with at least one plating layer including silver and forming an asper-silver layer comprising nano-silver formations over the at least one plating layer including silver. The asper-silver layer is particularly beneficial for enhancing the adhesion of plastic molding compound to the lead frame.

### FIELD OF THE INVENTION

The invention relates to lead frames for the assembly of semiconductor devices, and in particular to the plating of such lead frames for the enhancement of adhesion of plastic molding compound to the lead frames.

### BACKGROUND AND PRIOR ART

Lead frames are typically used as substrates for the assembly and packaging of semiconductor devices in mass production. In lead frame-based semiconductor packaging, silver (Ag) plating is a common lead frame surface finishing where wire bonding is conducted to electrically connect semiconductor chips to bond pads on the lead frames. In LED devices, silver plating also serves as a light reflection medium for improving the optical performance of the LED devices. After wire bonding, the semiconductor chips and wire bonds are encased in an encapsulant such as plastic molding compound to protect them from the external environment for incorporation into end-products. Good and strong adhesion between the surfacing finishing layer on the lead frame and plastic molding compound is one of the key factors determining package reliability and acceptability.

In particular, adequate adhesion of the plastic molding compound to the lead frame is important to resist penetration of moisture from the atmosphere into the package. This is especially important for LED packages in order to prevent defects from occurring. A common practice for assessing the resistance of LED packages to moisture attack is to conduct a dye penetration test, or the so-called “red ink test”, wherein red dye is applied to the package to determine whether the dye is able to penetrate the molding compound and leak into the package.

There are various approaches in the prior art to increase adhesion of plastic molding compound in order to ensure resistance of a semiconductor package to moisture attack. One approach uses a laser beam to mark a surface of the lead frame to roughen it. A rougher lead frame surface leads to better mechanically locking between the plastic molding compound and the lead frame surface. Nevertheless, laser-marking on the silver surface is costly and results in low productivity

Another conventional approach is to mold the lead frame prior to silver plating. This is because the base copper material in the lead frame exhibits stronger adhesion with molding compound than silver. Its disadvantage is that silver plating conducted after molding exposes the white plastic molding compound that is commonly used for LED devices to chemical attack by the plating chemicals. This causes the white plastic molding compound to discolor and turn yellowish. Moreover, the chemical attack has a negative effect on the

LED light output intensity, as well as results in faster decay of the semiconductor components inside the package.

A further conventional approach is to use electro-chemical deflash or sand-blasting to chemically or mechanically remove the undesirable mold flash left behind on the lead frame surface for improving the adhesion of plastic molding compound. However, wet chemical deflash processes often lead to delamination of molding compound from the lead frame, whilst sand-blasting is too harsh, heightening the risk of damaging the molding compound and making it crack. It will also reduce the brightness of the silver plating and tends to degrade the optical performance of the LED package.

### SUMMARY OF THE INVENTION

It is thus an object of the invention to seek to provide a silver plating method which avoids the aforesaid shortcomings of the prior art.

Accordingly, the invention provides a method for plating a lead frame, comprising the steps of: plating the lead frame with at least one plating layer including silver; and forming an asper-silver layer comprising nano-silver formations over the at least one plating layer including silver.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

Examples of plating processes in accordance with the invention will now be described with reference to the accompanying drawings, in which:

FIG. 1 is a schematic diagram illustrating the steps involved in the formation of an asper-silver plating on a lead frame used for LED packages;

FIG. 2 is an illustration of a forward and reverse current that is applicable during asper-silver plating;

FIG. 3 is a flowchart showing a process flow of a plating method according to a first preferred embodiment of the invention; and

FIG. 4 is a flowchart showing a process flow of a plating method according to a second preferred embodiment of the invention.

### DETAILED DESCRIPTION OF THE PREFERRED EMBODIMENT OF THE INVENTION

FIG. 1 is a schematic diagram illustrating the steps involved in the formation of an asper-silver plating 14 on a lead frame 10 used for LED packages. The base lead frame 10 is first formed by either conventional stamping or chemical etching to form the desired features such as die pads and tie-bars of the lead frame 10. Typically, the lead frame 10 comprises copper (Cu) or a copper alloy.

At least one plating layer 12 is then formed on the base lead frame 10 as required in the final product. The at least one plating layer 12 includes silver. After the step of forming the at least one plating layer 12, asper-plating is performed in order to form a layer of asper-silver 14 on the surface of the lead frame 10. “Asper” refers to the roughness of the surface of the silver plating that is obtained.

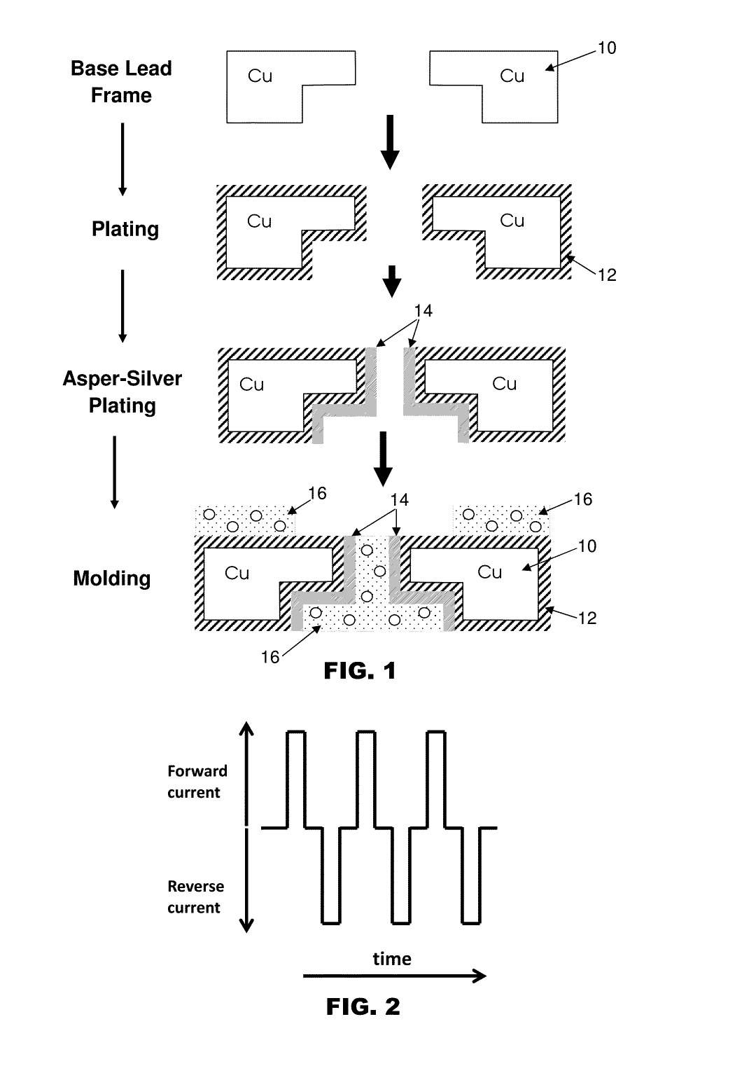

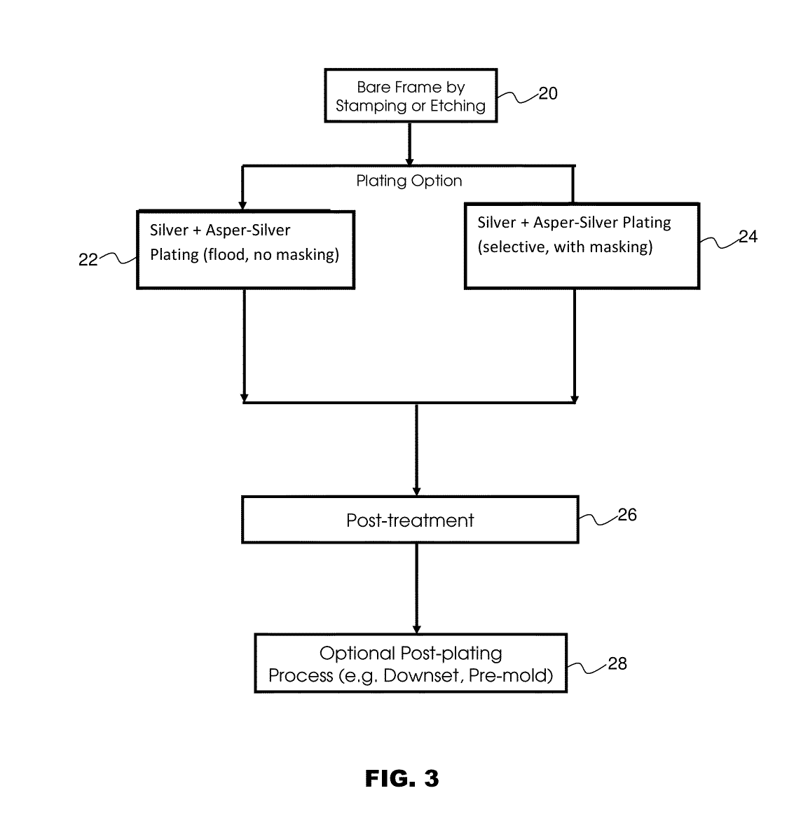

Electrochemical asper-silver plating is achieved by applying a forward and reverse pulse waveform current to a plating solution in which formation of the layer of asper-silver 14 is conducted. FIG. 2 is an illustration of a forward and reverse current that is applicable during such plating. The medium is a cyanide-based silver plating solution with organic additives. The ratio of forward and reverse currents may range from 5:1 to 100:1. The temperature under which the process is carried out is preferably 10° C. to 75° C., and the silver concentration is in the range of 10-100 g/L.

Asper-silver plating can be conducted by either chemical or electrochemical methods. Using the chemical method, the medium utilized may be an acidic or alkaline solution with organic and inorganic additives having a concentration of 1-100 g/L. The treatment time may be between 1 second and 45 seconds.

Chemicals used in an alkaline solution for asper-silver plating may comprise the salts of an organic acid such as acetate, lactate, carbonate, citrate or tartrate, in which an alkaline solution is formed after dissolution of the salts.

Chemicals used in an acidic solution for asper-silver plating may comprise an organic acid such as acetic acid, lactic acid, carbonic acid, citric acid or tartaric acid. Additives such as sodium dodecyl sulfate (SDS) or alkyltrimethylammonium salts are included. All the above solutions should preferably have a silver content of up to 1,000 ppm. Using the electrochemical method in the presence of a DC current having a current density of 10-200 ASD, the medium or plating solution utilized may be an alkaline solution having a concentration of 1-100 g/L. The process temperature may be between 10° C. to 50° C., and the treatment time may range between 1 second and 10 seconds.

For asper-silver plating in the presence of a DC current, a suitable recipe for the plating solution may be as follows:

Potassium carbonate—20-40 g/L
Lactic acid—10-30 g/L
Sodium dodecyl sulfate (SDS)—0.1-5 ml/L
Silver ion—500 ppm

During the asper-silver plating processes as described above, micelles are created in the presence of silver to form micelle-silver. Electrochemical or chemical reactions between such micelle-silver and the silver surface layer lead to the development of nano-silver formations (which dimensions are on a scale of nanometres) according to the sizes of the micelle-silver created, and the spread of nano-silver over the silver surface layer. The nano-silver formations are in the shape of dendrites, which increases the roughness of the layer of asper-silver 14.

In the illustration shown in FIG. 1, only the surfaces on indented portions of the base lead frame 10 are selectively plated with a layer of asper-silver 14. Thus, other surfaces of lead frame 10 where asper-silver plating is not required may be masked by masking tape, photo-resist film or other means. After the layer of asper-silver 14 has been plated, the masks are removed.

Finally, the lead frame 10 is ready to be molded with a plastic molding compound 16. The parts of the lead frame 10 corresponding to the areas containing a layer of asper-silver 14 has enhanced adhesion of plastic molding compound 16 to the surfaces of the lead frame 10 to reduce the risk of delamination of the plastic molding compound 16.

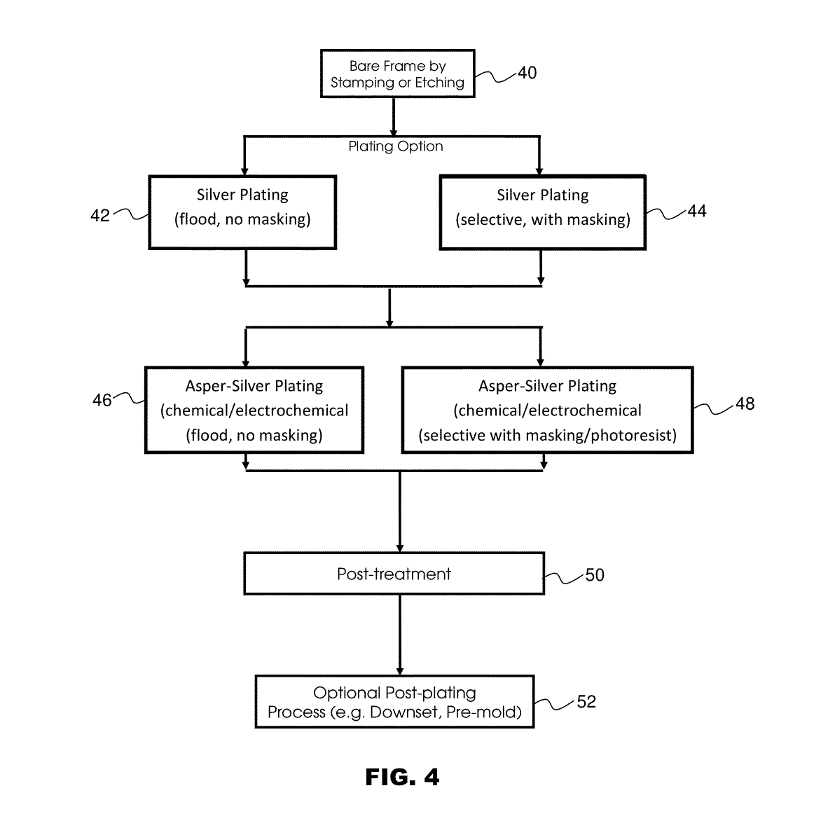

FIG. 3 is a flowchart showing a process flow of a plating method according to a first preferred embodiment of the invention. In this first preferred embodiment, the plating process is conducted in a single step, such that plating of the at least one plating layer 12 and formation of the layer of asper-silver 14 are conducted in a same plating solution.

First, the base lead frame is formed by either conventional stamping or chemical etching 20. Thereafter, silver and asper-silver plating are performed at the same time. The user may choose to either flood the lead frame with the plating solution without masking 22, or to selectively perform silver and asper-silver plating by masking portions of the lead frame where such plating is not desired 24. Asper-silver plating is generally desired and would be selectively formed on portions of the lead frame 10 that are intended to be molded using plastic molding compound in a molding process.

After silver and asper-silver plating, the plated lead frame is sent for post-treatment 26 to remove remnants of plating chemicals. Post-treatment 26 may comprise acid rinsing and the application of anti-tarnish to the plated lead frame. Optionally, a post-plating process 28 may be further conducted, for instance, to down-set or pre-mold parts of the lead frame. After such processes, the lead frame 10 would be ready to be molded after die bonding and wire bonding are performed.

FIG. 4 is a flowchart showing a process flow of a plating method according to a second preferred embodiment of the invention. In this second preferred embodiment, the plating is conducted in two separate processes.

First, the base lead frame is first formed by either conventional stamping or chemical etching 40. Thereafter, silver plating is performed on the base lead frame in a first process. The user may choose to either flood the lead frame with the silver-plating solution without masking 42, or selectively perform silver and asper-silver plating by masking portions of the lead frame where such silver plating is not required 44.

After the lead frame has been plated with a layer of silver, formation of the asper-silver layer is separately conducted on it in a second process that is separate from the first process. The user may choose to either conduct asper-silver plating chemically or electro-chemically by flooding the lead frame without masking 46 or to conduct asper-silver plating chemically or electro-chemically by masking portions of the lead frame where asper-silver plating is not required 48.

After conducting the silver and asper-silver plating processes separately, the plated lead frame is sent for post-treatment 26 to remove remnants of plating chemicals. Optionally, a post-plating process 28 may be further conducted, for instance, to down-set or pre-mold parts of the lead frame. After such processes, the lead frame 10 would be ready to be molded after die bonding and wire bonding are performed.

It should be appreciated that the asper-silver plating process as described according to the preferred embodiments of the invention is a special plating process that creates unique 3-D micro-fine dendrite-like morphology on the silver plating. It can achieve all-over surface roughness, or surface roughness only on selective areas by masking. The creation of 3-D micro-fine dendrite-like morphology on the silver plating enables intimate contact with molding compound in order to securely anchor it. Moreover, it effectively eliminates gaps formed by electro-chemical deflash processes and is highly resistant to moisture penetration from the external environment into the packaging.

There are many advantages of asper-silver plating on LED and other lead frames for enhancing adhesion of plastic molding compound. Not only is it a direct method to enhance adhesion between silver plating and the molding compound, it can also be applied to lead frames that are formed either by stamping or etching, and which have been silver plated.

By achieving strong adhesion between a silver layer of the lead frame and the plastic molding compound, the bending strength of end-product is also improved. In particular, selective asper-silver plating by masking will not roughen the silver plating that is exposed inside a reflector cup on which the LED chip is mounted, and thus avoids deteriorating the optical performance of the LED device.

The invention described herein is susceptible to variations, modifications and/or additions other than those specifically described and it is to be understood that the invention includes all such variations, modifications and/or additions which fall within the spirit and scope of the above description.

1. A method for plating a lead frame, comprising the steps of:
plating the lead frame with at least one plating layer including silver; and
forming an asper-silver layer comprising nano-silver formations over the at least one plating layer including silver.

2. The method as claimed in claim 1, wherein the step of forming the asper-silver layer further comprises the step of creating micelles in the presence of silver to form micelle-silver which react with the silver to develop the nano-silver formations over the at least one plating layer including silver.

3. The method as claimed in claim 1, wherein the step of forming the asper-silver layer is conducted while applying a forward and reverse pulse waveform current to a plating solution in which formation of the asper-silver layer is conducted.

4. The method as claimed in claim 1, wherein formation of the asper-silver layer is conducted in a plating solution comprising a cyanide-based silver plating solution having a silver concentration of 10-100 g/L.

5. The method as claimed in claim 4, wherein the formation of the asper-silver layer is carried out at a temperature of 10° C. to 75° C.

6. The method as claimed in claim 1, wherein the asper-silver layer is formed by chemical plating in a plating solution having a silver content of up to 1,000 ppm.

7. The method as claimed in claim 6, wherein the plating solution utilized for chemical plating comprises an acidic or alkaline solution with organic and inorganic additives having a concentration of 1-100 g/L.

8. The method as claimed in claim 6, wherein the step of chemical plating is conducted for a duration of between 1 second and 45 seconds.

9. The method as claimed in claim 6, wherein the alkaline solution comprises dissolved acetate, lactate, citrate or tartrate salts.

10. The method as claimed in claim 6, wherein the acidic solution comprises:
acetic acid, lactic acid, carbonic acid, citric acid or tartaric acid; and
sodium dodecyl sulfate or alkyltrimethylammonium salts as additives.

11. The method as claimed in claim 1, wherein the asper-silver layer is formed by electrochemical plating in the presence of a direct current having a current density of 10-200 ASD.

12. The method as claimed in claim 11, wherein a plating solution utilized for electrochemical plating is an alkaline solution comprising potassium carbonate, lactic acid, sodium dodecyl sulfate and silver ions.

13. The method as claimed in claim 11, wherein the step of electrochemical plating is carried out at a temperature of 10° C. to 50° C.

14. The method as claimed in claim 11, wherein the step of electrochemical plating is carried out for a duration of between 1 second and 10 seconds.

15. The method as claimed in claim 1, wherein the asper-silver layer is selectively formed on portions of the lead frame that are intended to be molded using plastic molding compound in a later process.

16. The method as claimed in claim 15, wherein the asper-silver layer is selectively formed by masking portions of the lead frame where the said asper-silver layer is not desired.

17. The method as claimed in claim 1, wherein the step of plating the lead frame with at least one plating layer including silver and the step of forming the asper-silver layer are conducted in a same plating solution.

18. The method as claimed in claim 1, wherein the step of plating the lead frame with at least one plating layer including silver is conducted in a first process, and thereafter, formation of the asper-silver layer is conducted in a second process that is separate from the first process.
